(19) United States
(12) Patent Application Publication
(10) Pub. No.: US 2026/0280387 A1
(43) Pub. Date: Sep. 17, 2026

(54) MAGNETIC SENSOR DEVICE, ROTATION DETECTION SYSTEM INCLUDING THE SAME, AND MAGNETIC FIELD GENERATION DEVICE

(71) Applicant: TDK Corporation, Tokyo (JP)

(72) Inventor: Yosuke KOMASAKI, Tokyo (JP)

(73) Assignee: TDK Corporation, Tokyo (JP)

(21) Appl. No.: 19/550,380

(22) Filed: Feb. 26, 2026

(30) Foreign Application Priority Data
Mar. 14, 2025 (JP) 2025-040800

(51) Int. Cl. H02K 11/215; G01R 31/34; G01R 33/00; G01R 33/038; H02K 1/32; H02K 7/00

(52) U.S. Cl. CPC H02K 11/215; G01R 31/343; G01R 33/0017; G01R 33/038; H02K 1/32; H02K 7/003

(57) ABSTRACT

A hollow shaft is formed of a ferromagnetic body, and holds a refrigerant at an inner circumferential side. A magnet is positioned at an outer circumferential side of the hollow shaft, and includes N pole and S pole adjacent in a circumferential direction of the hollow shaft. A magnetic sensor detects a magnetic field of the magnet. The hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.

### CROSS-REFERENCE TO RELATED APPLICATION

This application claims the benefit of Japanese Priority Patent Application No. 2025-040800, filed on Mar. 14, 2025, the entire contents of which are incorporated herein by reference.

### BACKGROUND

The disclosure relates to a magnetic sensor device, a rotation detection system including the magnetic sensor device, and a magnetic field generation device.

For example, JP 2006-042506A describes a motor including a hollow shaft, a sensing magnet fixed to an outer circumference of a sensor shaft of the hollow shaft, and a magnetic sensor provided at an outer circumferential side so as to face the sensing magnet. However, J P 2006-042506A may cause a decrease in a signal magnetic field of the sensing magnet due to thermal demagnetization resulting from heat generation resulting from high-speed rotation of the hollow shaft.

JP 2023-004958A and JP 2023-006087A describes that a refrigerant is received via the hollow shaft. However, when a leakage magnetic field from the sensing magnet extends into an inside of the hollow shaft, foreign substances containing a ferromagnetic body may be captured, which may hinder a flow of the refrigerant.

### SUMMARY

A magnetic sensor device according to one embodiment of the disclosure includes a hollow shaft that is formed of a ferromagnetic body and holds a refrigerant at an inner circumferential side, a magnet that is positioned at an outer circumferential side of the hollow shaft and includes N pole and S pole adjacent in a circumferential direction of the hollow shaft, and a magnetic sensor that detects a magnetic field of the magnet. The hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.

A rotation detection system according to an embodiment of the disclosure includes the magnetic sensor device described above, and a driving device that rotates the hollow shaft.

A magnetic field generation device according to an embodiment of the disclosure includes a hollow shaft that is formed of a ferromagnetic body and holds a refrigerant at an inner circumferential side, and a magnet that is positioned at an outer circumferential side of the hollow shaft and includes N pole and S pole adjacent in a circumferential direction of the hollow shaft. The hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device according to a first example embodiment of the disclosure.

FIG. 2 is a sectional view showing the magnetic sensor device according to the first example embodiment of the disclosure.

FIG. 3A is a diagram showing variations in circumferential length based on adjacent N and S poles of a magnet in one example embodiment of the disclosure; FIG. 3B is a diagram showing variations in circumferential length based on adjacent N and S poles of a magnet in another example embodiment of the disclosure; and FIG. 3C is a diagram showing variations in circumferential length based on adjacent N and S poles of a magnet in yet another example embodiment of the disclosure.

FIG. 4A is a diagram showing a leakage magnetic field path from a magnet in the first example embodiment of the disclosure; and FIG. 4B is a diagram showing a leakage magnetic field path from a magnet in a comparative example in a comparable manner.

FIG. 5 is a circuit diagram showing a configuration of the magnetic sensor in the first example embodiment of the disclosure.

FIG. 6 is a schematic diagram showing an example of a vehicle on which a magnetic sensor device of a second example embodiment of the disclosure is mounted.

### DETAILED DESCRIPTION

An object of the disclosure is to provide a magnetic sensor device capable of reducing a leakage magnetic field into an inside of a hollow shaft, improving the cooling efficiency by a refrigerant inside the hollow shaft, and achieving favorable sensing, a rotation detection system including the magnetic sensor device, and a magnetic field generation device.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

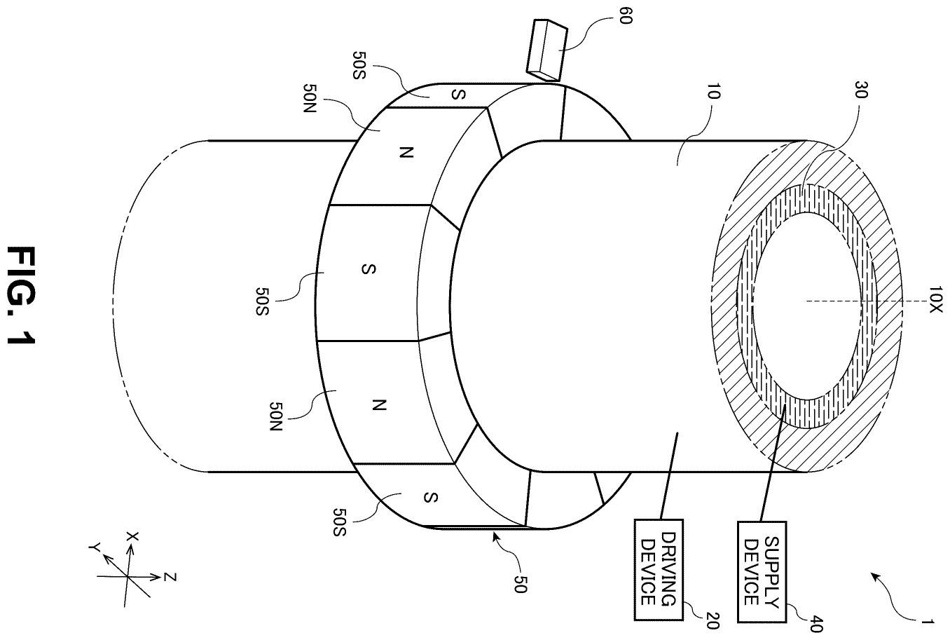

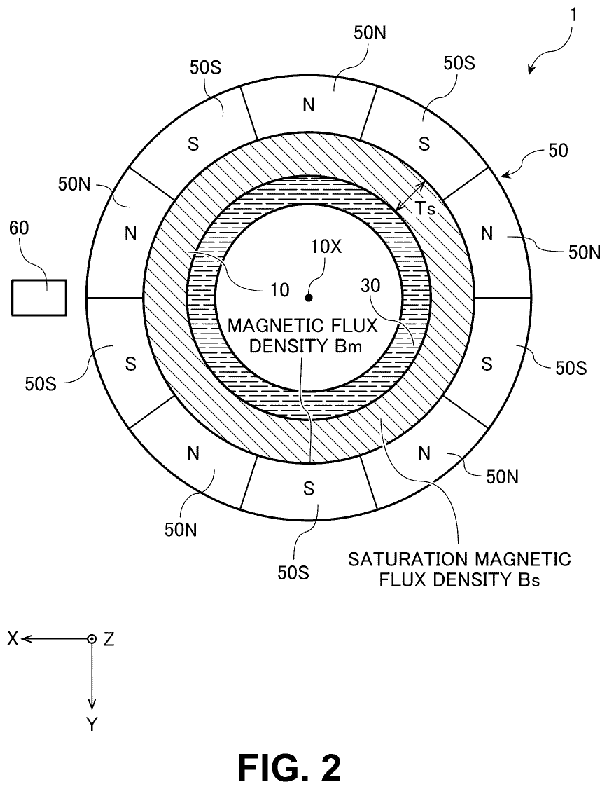

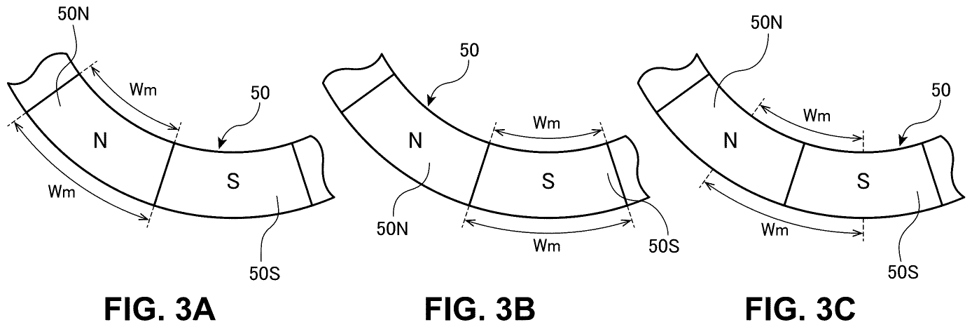

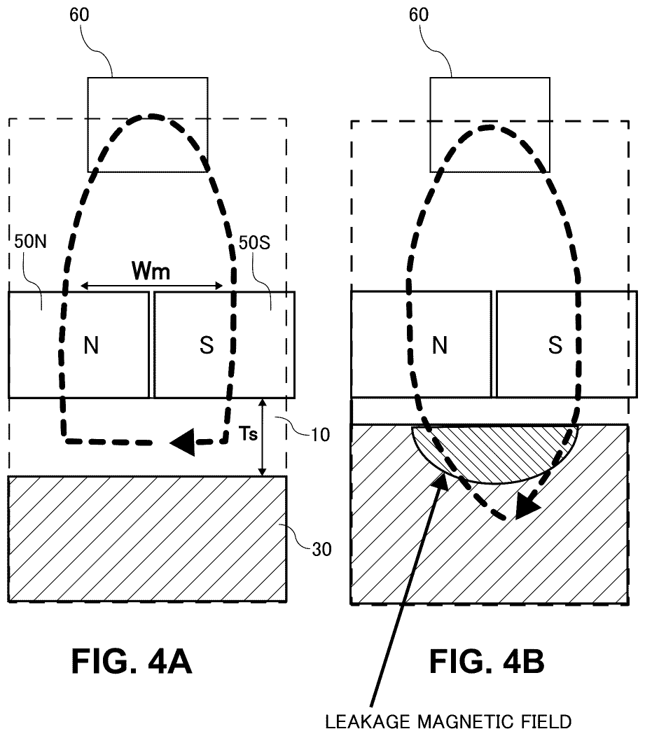

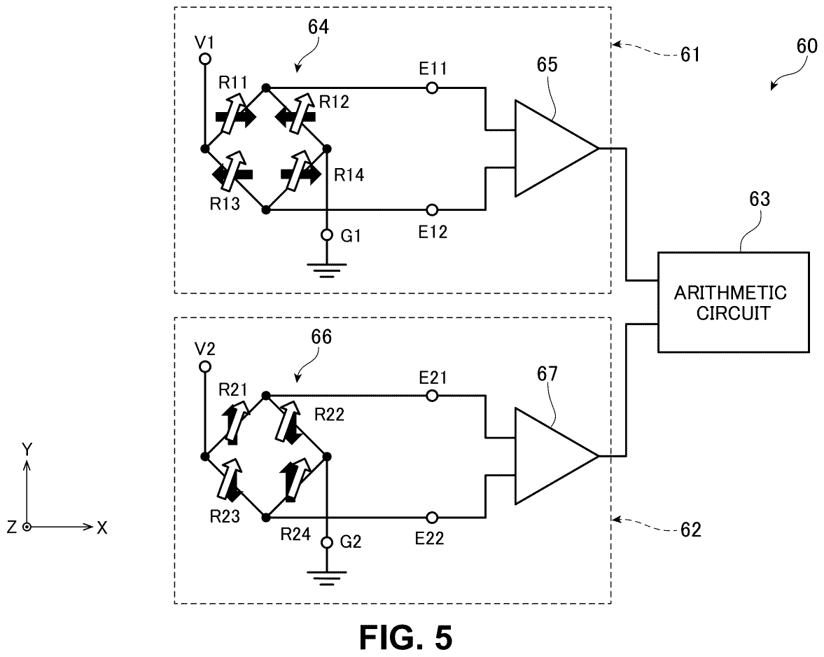

First, with reference to FIG. 1 to FIG. 5, a schematic configuration of a magnetic sensor device according to a first example embodiment of the disclosure is described. FIG. 1 is a perspective view showing the magnetic sensor device. FIG. 2 is a sectional view showing the magnetic sensor device. FIG. 3A to FIG. 3C are diagrams showing variations in circumferential length based on adjacent N and S poles of a magnet. FIG. 4A and FIG. 4B are diagrams showing a leakage magnetic field path from a magnet and a leakage magnetic field path from a magnet in a comparative example in a comparable manner. FIG. 5 is a circuit diagram showing the configuration of the magnetic sensor.

A magnetic sensor device 1 includes a hollow shaft (rotor shaft) 10 that is formed of a ferromagnetic body. The hollow shaft 10 is formed of a ferromagnetic material whose thermal conductivity is equal to or higher than that of silicon steel (the thermal conductivity of silicon steel is 28.5 (at 100 degrees Celsius)), and may contains, for example, iron, carbon steel, silicon steel, chromium molybdenum steel, or the like. The hollow shaft 10 is connected to a driving device (driving source) 20 that rotates the hollow shaft 10 about a rotation axis (center axis) 10X in the longitudinal direction. In FIG. 1, the driving device 20 is shown in a schematic block diagram. However, the driving device 20 may include a driving motor and a transmission member (driving gear) that transmits a driving force of the driving motor to the hollow shaft. A rotational speed of the hollow shaft 10 by the driving device 20 may be a high rotational speed based on, for example, 1 kilo revolutions per minute (krpm).

The driving device 20 may be considered as a component of the magnetic sensor device 1, or may be considered as not a component of the magnetic sensor device 1. In the latter case, the magnetic sensor device 1 and the driving device 20 that rotates the hollow shaft 10 may be combined to configure a rotation detection system that detects a rotational position, a rotational speed, a rotational change amount, and the like of the hollow shaft 10.

A refrigerant (coolant) 30 is held at the inner circumferential side of the hollow shaft 10. The refrigerant 30 may have a density higher than that of air, and is configured by a material, such as water, ethylene glycol, and oil for oil cooling, having a thermal conductivity of approximately 0.05 (W/m·K). The refrigerant 30 includes a function of reducing an influence of heat generation (for example, thermal demagnetization) resulting from rotation of the hollow shaft 10 by the driving device 20. The magnetic sensor device 1 may include a supply device 40 that supplies the refrigerant 30 to the inner circumferential side of the hollow shaft 10. In FIG. 1, the supply device 40 is shown in a schematic block diagram. However, the supply device 40 may include a pump, a circulation device, and the like that are sealed at the inner circumferential side of the hollow shaft 10.

As shown in FIG. 1 and FIG. 2, when the driving device 20 rotates the hollow shaft 10, the refrigerant 30 may be held in a state of facing (being in close contact with) the inner circumferential surface of the hollow shaft 10 by a centrifugal force generated by rotation of the hollow shaft 10. In other words, as the inner space of the hollow shaft 10 is seen in a section view, the refrigerant 30 may not be positioned in a circular part at the center, and the refrigerant 30 may be positioned only in an annular part on the periphery side.

At the outer circumferential side of the hollow shaft 10, an annular magnet (multipole magnet) 50 is positioned. The magnet 50 is fitted to the outer circumferential surface of the hollow shaft 10 via a resin layer (resin film) omitted in illustration. Thus, when the driving device 20 rotates the hollow shaft 10, the magnet 50 fitted to the hollow shaft 10 is also rotated integrally. The magnet 50 includes an N pole 50N and an S pole 50S that are adjacent to each other in the circumferential direction of the hollow shaft 10. In the example in FIG. 1 and FIG. 2, five N poles 50N and five S poles 50S are arranged side by side in the circumferential direction at an equal interval (an interval of 36 degrees). However, the numbers, arrangement, size, and the like of the N poles 50N and the S poles 50S that configure the magnet 50 may have degrees of freedom, and various design modifications may be made thereto. In the example of FIG. 1, the magnet 50 is attached between one end and the other end of the hollow shaft 10 in the axial direction (in the part except for the ends). However, the attachment position of the magnet 50 to the hollow shaft 10 has a degree of freedom, and various design modifications may be made thereto. The attachment structure of the magnet 50 to the hollow shaft 10 also has a degree of freedom, and various design modifications may be made thereto (it is only required that the magnet 50 be positioned at the outer circumferential side of the hollow shaft 10).

For example, when the annular magnet 50 is fitted to the outer circumferential surface of the hollow shaft 10, heat of the hollow shaft 10 may be transferred to the annular magnet 50. However, the refrigerant 30 held at the inner circumferential side of the hollow shaft 10 serves as a function of cooling the hollow shaft 10, thus the annular magnet 50. The cooling effect is exerted more prominently by setting a first function relating to a shape and characteristics of the hollow shaft 10 and a second function relating to a shape and characteristics of the magnet 50 as appropriate so as to satisfy Conditional Expression (1) described below.

As shown in FIG. 1 and FIG. 2, a magnetic sensor 60 that detects a magnetic field of the magnet 50 is positioned at the outer circumferential side of the magnet 50. The magnetic sensor 60 is arranged away from the hollow shaft 10 in the radial direction of the hollow shaft 10 between the one end and the other end of the hollow shaft 10 in the axial direction (in the part except for the ends), and is arranged at a position corresponding to (overlapping with or common with) the magnet 50 in the axial direction. However, as long as a magnetic field of the magnet 50 can be detected, the type, number, arrangement, size, and the like of the magnetic sensor 60 have degrees of freedom, and various design modifications may be made thereto.

The magnetic sensor device 1 is configured to detect a physical amount relating to a positional relationship, a positional change speed, a positional change amount, or the like in the circumferential direction between the magnet 50 that is fixed to the hollow shaft 10 and the magnetic sensor 60 that is arranged away from the hollow shaft 10 to the outside in the radial direction of the hollow shaft 10 when the driving device 20 rotates the hollow shaft 10.

Here, with reference to FIG. 1 and FIG. 2, the direction definitions in the example embodiment are described. First, a direction that is parallel to the rotation axis 10X shown in FIG. 1 and extends from the lower side to the upper side in FIG. 1 is defined as a Z direction. In FIG. 2, the Z direction is shown as a direction from the near side to the far side of FIG. 2. Next, two mutually orthogonal directions perpendicular to the Z direction are defined as the X and Y directions. In FIG. 2, the X direction is represented as a direction extending to the left side, and the Y direction is represented as a direction extending to the lower side. The opposite directions to the X, Y, and Z directions are defined as −X, −Y, and −Z directions, respectively.

The magnetic sensor 60 includes a detection circuit shown in FIG. 5. The magnetic sensor 60 detects a magnetic field applied to the magnetic sensor 60, and outputs a detection signal that is changed in response to the detected magnetic field. The magnetic sensor 60 includes a first detection circuit 61, a second detection circuit 62, and an arithmetic circuit 63. The first detection circuit 61 and the second detection circuit 62 each detects a direction of a magnetic field applied from the magnet 50, and outputs a signal indicating the direction. The arithmetic circuit 63 calculates a detection value of an angle formed by the direction of the magnetic field applied from the magnet 50 with respect to a reference direction, based on the output signals of the first detection circuit 61 and the second detection circuit 62. The arithmetic circuit 63 may further calculate a physical amount relating to a positional relationship, a positional change speed, a positional change amount, or the like in the circumferential direction between the magnet 50 and the magnetic sensor 60, based on a detection value of an angle.

Each of the first detection circuit 61 and the second detection circuit 62 includes at least one magnetic detection element. Each of the first detection circuit 61 and the second detection circuit 62 may include a pair of magnetic detection elements connected in series as the at least one magnetic detection element. In such a case, each of the first detection circuit 61 and the second detection circuit 62 may include a wheatstone bridge circuit including a first pair of magnetic detection elements connected in series and a second pair of magnetic detection elements connected in series. A case in which each of the first detection circuit 61 and the second detection circuit 62 includes the above-mentioned wheatstone bridge circuit is described below as an example.

The first detection circuit 61 includes the wheatstone bridge circuit 64 and a differential detector 65. The wheatstone bridge circuit 64 includes a power supply port V1, a ground port G1, two output ports E11 and E12, a first pair of magnetic detection elements R11 and R12 connected in series, and a second pair of magnetic detection elements R13 and R14 connected in series. One end of each of the magnetic detection elements R11 and R13 is connected to the power supply port V1. The other end of the magnetic detection element R11 is connected to one end of the magnetic detection element R12 and the output port E11. The other end of the magnetic detection element R13 is connected to one end of the magnetic detection element R14 and the output port E12. The other end of each of the magnetic detection elements R12 and R14 is connected to the ground port G1. A voltage or an electric current having a specific magnitude is applied to the power supply port V1. The ground port G1 is connected to the ground. The differential detector 65 outputs a signal corresponding to a potential difference between the output ports E11 and E12 to the arithmetic circuit 63.

The second detection circuit 62 includes a wheatstone bridge circuit 66 and a differential detector 67. The wheatstone bridge circuit 66 includes a power supply port V2, a ground port G2, two output ports E21 and E22, a first pair of magnetic detection elements R21 and R22 connected in series, and a second pair of magnetic detection elements R23 and R24 connected in series. One end of each of the magnetic detection elements R21 and R23 is connected to the power supply port V2. The other end of the magnetic detection element R21 is connected to one end of the magnetic detection element R22 and the output port E21. The other end of the magnetic detection element R23 is connected to one end of the magnetic detection element R24 and the output port E22. The other end of each of the magnetic detection elements R22 and R24 is connected to the ground port G2. A voltage or an electric current having a specific magnitude is applied to the power supply port V2. The ground port G2 is connected to the ground. The differential detector 67 outputs a signal corresponding to a potential difference between the output ports E21 and E22 to the arithmetic circuit 63.

In the example embodiment, as all the magnetic detection elements included in the wheatstone bridge circuits 64 and 66, an AMR element or a spin-valve MR element (hereinafter, simply referred to as an MR element) may be used. As the MR element, in particular, a TMR element may be used. Note that, in place of the TMR element, a GMR element may be used. The TMR element or the GMR element includes a magnetization pinned layer whose magnetization direction is fixed, a free layer whose magnetization direction is variable according to a direction of an applied magnetic field, and a non-magnetic layer arranged between the magnetization pinned layer and the free layer. In the TMR element, the non-magnetic layer is a tunnel barrier layer. In the GMR element, the non-magnetic layer is a nonmagnetic conductive layer. The resistance of the TMR element or the GMR element is changed with the angle that the magnetization direction of the free layer forms with respect to the magnetization direction of the magnetization pinned layer. The resistance is at its minimum value when the foregoing angle is 0 degrees, and at its maximum value when the foregoing angle is 180 degrees.

Each of the plurality of magnetic detection elements included in the wheatstone bridge circuits 64 and 66 may include one MR element, or may include a plurality of MR elements. A case in which the magnetic detection element included in the wheatstone bridge circuits 64 and 66 includes at least one MR element is described below as an example. In FIG. 5, solid arrows represent the magnetization direction of the magnetization pinned layer in the MR element, and hollow arrows represent the magnetization direction of the free layer in the MR element.

In the first detection circuit 61, the magnetization direction of the magnetization pinned layer of the MR element in the magnetic detection elements R11 and R14 is the X direction, and the magnetization direction of the magnetization pinned layer of the MR element in the magnetic detection elements R12 and R13 is the −X direction. In such a case, a potential difference between the output ports E11 and E12 is changed according to an angle formed by the applied magnetic field with respect to the X direction. Therefore, the first detection circuit 61 detects an angle formed by the direction of the applied magnetic field with respect to the X direction, and outputs a signal indicating the angle.

In the second detection circuit 62, the magnetization direction of the magnetization pinned layer of the MR element in the magnetic detection elements R21 and R24 is the Y direction, and the magnetization direction of the magnetization pinned layer of the MR element in the magnetic detection elements R22 and R23 is the −Y direction. In such a case, a potential difference between the output ports E21 and E22 is changed according to an angle formed by the applied magnetic field with respect to the Y direction. Therefore, the second detection circuit 62 detects an angle formed by the direction of the applied magnetic field with respect to the Y direction, and outputs a signal indicating the angle.

In the example shown in FIG. 5, the magnetization direction of the magnetization pinned layer of the MR element in the second detection circuit 62 is orthogonal to the magnetization direction of the magnetization pinned layer of the MR element in the first detection circuit 61. Ideally, a waveform of the output signal of the first detection circuit 61 is a cosine waveform, and a waveform of the output signal of the second detection circuit 62 is a sine waveform.

Here, as a sensor that detects a rotational speed and a rotational angle of a motor, a resolver that utilizes a principle of a transformer has been known. In the resolver, a relative position between a primary winding and a secondary winding is changed by rotation of the motor, and detecting the change as an electrical signal allows detection of the rotational speed and the rotational angle of the motor.

On the other hand, in order to meet demands for size reduction and weight reduction, a shaft detection mechanism using a magnetic sensor such as one in the example embodiment, in place of the above-mentioned resolver, has also been known. Such a shaft detection mechanism involves shaft-end detection and shaft-outer-periphery detection. In shaft-outer-periphery detection such as one in the example embodiment, a magnet (multipole magnet) is fixed to a shaft (rotor shaft), and its magnetic field is detected by a magnetic sensor. When the magnet is fixed to the shaft, which rotates at high speed, the shaft may be made hollow, and a refrigerant (coolant) may be provided inside the hollow shaft in order to prevent a signal magnetic field from decreasing due to thermal demagnetization resulting from heat generation. However, when a leakage magnetic field from the magnet extends into an inside of the hollow shaft, foreign substances containing a ferromagnetic body in the refrigerant may be captured, which may hinder a flow of the refrigerant. Examples of foreign substances containing a ferromagnetic body include machining residues of a rotation detection system including the shaft and wear particles generated by wear of a driving device.

In the magnetic sensor device 1 of the example embodiment, in order to solve the technical problems described above, a leakage magnetic field into the inside of the hollow shaft 10 is reduced by setting the shapes and characteristics of the hollow shaft 10 and the magnet 50 as appropriate. With this, the cooling efficiency inside the hollow shaft 10 by the refrigerant 30 is improved, and favorable sensing is achieved.

More specifically, the hollow shaft 10 and the magnet 50 are configured so that the first function relating to the shape and characteristics of the hollow shaft 10 and the second function relating to the shape and characteristics of the magnet 50 satisfy the condition for reducing a leakage magnetic field from the magnet 50 from the outer circumferential side to the inner circumferential side of the hollow shaft 10.

As the first function relating to the shape and characteristics of the hollow shaft 10, a function in which at least one of a saturation magnetic flux density Bs of the hollow shaft 10 and a thickness Ts of the hollow shaft 10 is a variable is defined. In the example embodiment, the product Bs×Ts of the saturation magnetic flux density Bs of the hollow shaft 10 and the thickness Ts of the hollow shaft 10 may be defined as the first function. In FIG. 2, the saturation magnetic flux density Bs of the hollow shaft 10 is denoted with a conceptual reference symbol, and a length corresponding to the thickness Ts of the hollow shaft 10 is denoted with a reference symbol. Note that, as described above, the magnet 50 is fitted to the outer circumferential surface of the hollow shaft 10 via a resin layer (resin film) omitted in illustration. Therefore, there is a gap length corresponding to the resin layer between the outer circumferential surface of the hollow shaft 10 and the inner circumferential surface of the magnet 50. However, in the present embodiment, it is assumed that the thickness Ts of the hollow shaft 10 does not include a gap length corresponding to the resin layer. Note that, when the gap length exists, a part of the magnetic flux of the magnet 50 does not reach the hollow shaft 10, and returns to the magnet 50 by circulating through the gap. In such a case, by setting the first function relating to the shape and characteristics of the hollow shaft 10 and the second function relating to the shape and characteristics of the magnet 50 as appropriate so as to satisfy Conditional Expression (1) described below, the cooling effect on the hollow shaft 10, specifically, the annular magnet 50 by the refrigerant 30 can be exerted prominently.

A function in which at least one of a magnetic flux density Bm on the surface of the magnet 50 at the inner circumferential side and a circumferential length Wm based on the adjacent N pole 50N and S pole 50S of the magnet 50 is a variable is defined as the second function relating to the shape and characteristics of the magnet 50. In the example embodiment, as the second function, the product Bm×Wm of the magnetic flux density Bm on the surface of the magnet 50 at the inner circumferential side and the circumferential length Wm based on the adjacent N pole 50N and S pole 50S of the magnet 50 may be defined. In FIG. 2, the magnetic flux density Bm on the surface of the magnet 50 at the inner circumferential side is denoted with a conceptual reference symbol.

With reference to FIG. 3A to FIG. 3C, variations of the circumferential length Wm based on the adjacent N pole 50N and S pole 50S of the magnet 50 are described.

In the example of FIG. 3A, the width of the N pole 50N of the magnet 50 in the circumferential direction is defined as the length Wm. The width of the N pole 50N of the magnet 50 in the circumferential direction differs between the inner circumferential side and the outer circumferential side (the width at the inner circumferential side is smaller than the width at the outer circumferential side), but the length Wm may be defined based on any one of the width at the inner circumferential side or the width at the outer circumferential side. Alternatively, the length Wm may be defined by taking an average of the width at the inner circumferential side and the width at the outer circumferential side.

In the example of FIG. 3B, the width of the S pole 50S of the magnet 50 in the circumferential direction is defined as the length Wm. The width of the S pole 50S of the magnet 50 in the circumferential direction differs between the inner circumferential side and the outer circumferential side (the width at the inner circumferential side is smaller than the width at the outer circumferential side), but the length Wm may be defined based on any one of the width at the inner circumferential side or the width at the outer circumferential side. Alternatively, the length Wm may be defined by taking an average of the width at the inner circumferential side and the width at the outer circumferential side.

In the example of FIG. 3C, the pitch between the adjacent N pole 50N and S pole 50S of the magnet 50 in the circumferential direction is defined as the length Wm. The pitch between the adjacent N pole 50N and S pole 50S of the magnet 50 in the circumferential direction differs between the inner circumferential side and the outer circumferential side (the pitch at the inner circumferential side is smaller than the pitch at the outer circumferential side), but the length Wm may be defined based on any one of the pitch at the inner circumferential side or the pitch at the outer circumferential side. Alternatively, the length Wm may be defined by taking an average of the pitch at the inner circumferential side and the pitch at the outer circumferential side.

Any one of the lengths Wm defined in FIG. 3A to FIG. 3C described above (for example, the largest length) may be used as the circumferential length Wm based on the adjacent N pole 50N and S pole 50S of the magnet 50.

The product Bs×Ts of the saturation magnetic flux density Bs of the hollow shaft 10 and the thickness Ts of the hollow shaft 10 may be greater than the product Bm×Wm of the magnetic flux density Bm on the surface of the magnet 50 at the inner circumferential side and the circumferential length Wm based on the adjacent N pole 50N and S pole 50S of the magnet 50. In other words, the first function and the second function may satisfy Conditional Expression (1) given below.

$$B s \times T s > B m \times W m \qquad ( 1 )$$

With this, a leakage magnetic field into the inside of the hollow shaft 10 is reduced, and adhesion and accumulation of foreign substances containing a ferromagnetic body on the inner circumferential surface of the hollow shaft 10 are suppressed. Accordingly, a flow rate of the refrigerant 30 inside the hollow shaft 10 can be secured to improve the cooling efficiency, and favorable sensing can be achieved.

The first function and the second function may satisfy at least one of Conditional Expressions (1A), (1B), (1C), and (1D) given below.

$$Bs \times Ts > 2 ( Bm \times Wm ) \qquad ( 1 A )$$

$$10 ( Bm \times Wm ) > Bs \times Ts > 2 ( Bm \times Wm ) \qquad ( 1 B )$$

$$7 ( Bm \times Wm ) > Bs \times Ts > 2 ( Bm \times Wm ) \qquad ( 1 C )$$

$$4 ( Bm \times Wm ) > Bs \times Ts > 2 ( Bm \times Wm ) \qquad ( 1 D )$$

When Conditional Expression (1A) is satisfied, a leakage magnetic field into the inside of the hollow shaft 10 can be reduced more to improve the cooling efficiency by the refrigerant 30 inside the hollow shaft 10, and favorable sensing can be achieved.

When Conditional Expression (1B) is satisfied, the actions and effects described with reference to Conditional Expression (1A) can be obtained. Moreover, excessive thickening can be prevented while securing rigidity of the hollow shaft 10, and a flow rate of the refrigerant 30 inside the hollow shaft 10 can be secured. Excessive multipolarization of the magnet 50 can be prevented, and simplification of the structure and facilitation of manufacturing can be achieved.

Here, a background of how Conditional Expression (1) holds is described in more detail. For a certain pole “a” of the magnet (multipole magnet), a magnetic flux φa passing through an inner surface Sa of the pole a is expressed by Equation (1-1). In Equation (1-1), Bm is a magnetic flux density of a minute area element on the surface Sa, and ds is the minute area element on the surface Sa.

$${ϕ}_{a} = {\int }_{{S}_{a}} {B}_{m} \cdot ds \qquad ( 1 - 1 )$$

A maximum magnetic flux φs, for which the hollow shaft functions as a yoke with respect to magnetic flux in a tangential direction, is expressed by Expression (1-2), where a shaft cross section that is cut out when the magnet is moved in the radial direction is Ss. In Expression (1-2), Bs is a saturation magnetic flux density of a shaft material, and ds is a minute area element in the cross section Ss. The reason why the expression is an inequality is that shaft portions at both ends of the cross section Ss also contribute as a yoke.

$${ϕ}_{S} > {\int }_{{S}_{s}} {B}_{s} \cdot ds \qquad ( 1 - 2 )$$

Since a condition for the magnetic flux φa to circulate inside the hollow shaft is φs>φa, it is sufficient that the condition expressed in Expression (1-3) be satisfied.

$${\int }_{{S}_{s}} {B}_{s} \cdot ds > {\int }_{{S}_{a}} {B}_{m} \cdot ds \qquad ( 1 - 3 )$$

In order to simplify Expression (1-3), it is assumed that the magnetic flux density on the surface Sa of the magnet (multipole magnet) is a constant value Bm, and that the area of the surface Sa can be approximated by Wm×Lm. Here, Wm is a pole width of the certain pole “a” of the magnet (multipole magnet). Lm is a length of the hollow shaft in the axial direction corresponding to the pole “a” of the magnet (multipole magnet). Further, assuming that a saturation magnetic flux density Bs of the shaft material of the hollow shaft is uniform and that a thickness Ts of the hollow shaft is also uniform, Expression (1-3) can be expressed as Expression (1-4), and Conditional Expression (1) can be obtained based on Expression (1-4) (by eliminating Lm from the left and right sides).

$$Bs \times ( Ts \times Lm ) > Bm \times ( Wm \times Lm ) \qquad ( 1 - 4 )$$

Therefore, a shaft design may be made so that Conditional Expression (1) holds for a pole having a maximum pole width among poles of the magnet (multipole magnet). In other words, the first function relating to the shape and characteristics of the hollow shaft 10 and the second function relating to the shape and characteristics of the magnet 50 may be set as appropriate so as to satisfy Conditional Expression (1).

FIG. 4A shows a leakage magnetic field path from the magnet 50 in the first example embodiment of the disclosure, and FIG. 4B shows a leakage magnetic field path from a magnet in the comparative example.

As shown in FIG. 4A, in the first example embodiment of the disclosure, the annular magnet 50 is fitted to the outer circumferential surface of the hollow shaft 10. Further, the first function relating to the shape and characteristics of the hollow shaft 10 and the second function relating to the shape and characteristics of the magnet 50 are set as appropriate so as to satisfy Conditional Expression (1). Thus, a leakage magnetic field into the inside of the hollow shaft 10 is reduced, and adhesion and accumulation of foreign substances containing a ferromagnetic body on the inner circumferential surface of the hollow shaft 10 are suppressed. Accordingly, a flow rate of the refrigerant 30 inside the hollow shaft 10 can be secured to improve the cooling efficiency with respect to the magnet 50 via the hollow shaft 10, and favorable sensing can be achieved. When the annular magnet 50 is fitted to the outer circumferential surface of the hollow shaft 10, heat of the hollow shaft 10 may be transferred to the annular magnet 50. However, by setting the first function relating to the shape and characteristics of the hollow shaft 10 and the second function relating to the shape and characteristics of the magnet 50 as appropriate so as to satisfy Conditional Expression (1), the cooling effect on the hollow shaft 10, specifically, the annular magnet 50 by the refrigerant 30 can be exerted prominently.

In contrast, in the comparative example shown in FIG. 4B, a leakage magnetic field from the magnet extends into the inside of the hollow shaft. As a result, foreign substances containing a ferromagnetic body are captured, which hinders a flow of the refrigerant.

### Second Example Embodiment

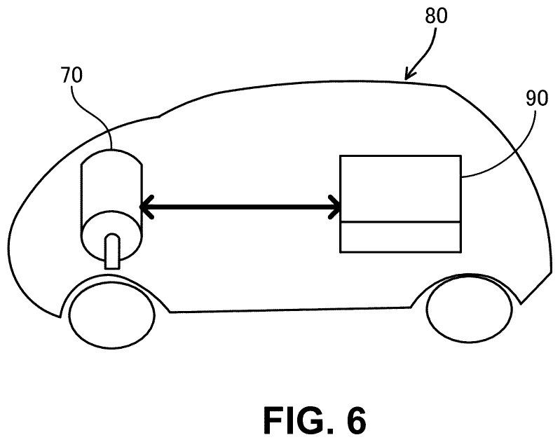

A second example embodiment of the disclosure relates to a driving shaft 70 including the magnetic sensor device 1 of the first example embodiment of the disclosure and a vehicle 80 on which the driving shaft 70 is mounted. FIG. 6 is a schematic diagram showing an example of the vehicle 80 on which the magnetic sensor device 1 of the second example embodiment of the disclosure is mounted.

The driving shaft 70 including the magnetic sensor device 1 is mounted on the vehicle 80, which is an electric vehicle (EV) that uses at least a motor as a power source, such as a hybrid electric vehicle (HEV), a plug-in hybrid electric vehicle (PHEV), and a battery electric vehicle (BEV), and is used as a driving source of the vehicle 80. The driving shaft 70 drives front wheels of the vehicle 80. The vehicle 80 includes a battery 90 that accumulates driving power to be supplied to the driving shaft 70. The battery 90 may configure the driving device 20 simply shown in FIG. 1.

### Third Example Embodiment

A third example embodiment of the disclosure relates to a magnetic field generation device from which the magnetic sensor 60 is omitted from (removed from the components of) the magnetic sensor device 1 of the first example embodiment of the disclosure. In other words, the magnetic field generation device of the third example embodiment of the disclosure includes the hollow shaft 10 that is formed of a ferromagnetic body and holds the refrigerant 30 at the inner circumferential side, and the magnet 50 that is positioned at the outer circumferential side of the hollow shaft 10 and includes the N pole 50N and the S pole 50S adjacent in the circumferential direction of the hollow shaft 10. Further, the hollow shaft 10 and the magnet 50 are configured so that the first function relating to the shape and characteristics of the hollow shaft 10 and the second function relating to the shape and characteristics of the magnet 50 satisfy a condition for reducing a leakage magnetic field from the magnet 50 from the outer circumferential side to the inner circumferential side of the hollow shaft 10 (for example, so as to satisfy Bs×Ts>Bm×Wm described above). A magnetic sensor device is obtained by attaching a magnetic sensor that detects a magnetic field of the magnet 50 (the type, number, arrangement, size, and the like of the magnetic sensor are not limited) to the magnetic field generation device of the third example embodiment of the disclosure.

As described above, a magnetic sensor device according to one embodiment of the disclosure includes a hollow shaft that is formed of a ferromagnetic body and holds a refrigerant at an inner circumferential side, a magnet that is positioned at an outer circumferential side of the hollow shaft and includes N pole and S pole adjacent in a circumferential direction of the hollow shaft, and a magnetic sensor that detects a magnetic field of the magnet. The hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.

In the magnetic sensor device according to the embodiment of the disclosure, as the first function, a product Bs×Ts of a saturation magnetic flux density Bs of the hollow shaft and a thickness Ts of the hollow shaft may be defined. as the second function, a product Bm×Wm of a magnetic flux density Bm on a surface of the magnet at the inner circumferential side and a circumferential length Wm based on the adjacent N and S poles of the magnet may be defined.

In the magnetic sensor device according to the embodiment of the disclosure, the circumferential length Wm based on the adjacent N and S poles of the magnet may include at least one of a circumferential width of the N pole, a circumferential width of the S pole, and a circumferential pitch between the N pole and the S pole.

In the magnetic sensor device according to the embodiment of the disclosure, Bs×Ts>Bm×Wm may be satisfied.

In the magnetic sensor device according to the embodiment of the disclosure, the refrigerant may have a density higher than that of air.

In the magnetic sensor device according to the embodiment of the disclosure, the hollow shaft may be formed of a ferromagnetic material whose thermal conductivity is equal to or higher than thermal conductivity of silicon steel.

In the magnetic sensor device according to the embodiment of the disclosure, the magnet may be arranged between one end and the other end of the hollow shaft in an axial direction.

In the magnetic sensor device according to the embodiment of the disclosure, the magnetic sensor may be arranged away from the hollow shaft in a radial direction of the hollow shaft between the one end and the other end of the hollow shaft in the axial direction.

A rotation detection system according to an embodiment of the disclosure may include the magnetic sensor device described above, and a driving device that rotates the hollow shaft.

The rotation detection system according to the embodiment of the disclosure may further include a supply device that supplies the refrigerant to the inner circumferential side of the hollow shaft.

A magnetic field generation device according to an embodiment of the disclosure includes a hollow shaft that is formed of a ferromagnetic body and holds a refrigerant at an inner circumferential side, and a magnet that is positioned at an outer circumferential side of the hollow shaft and includes N pole and S pole adjacent in a circumferential direction of the hollow shaft. The hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.

In the disclosure, the hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft. With this, according to the disclosure, a leakage magnetic field into an inside of a hollow shaft can be reduced, the cooling efficiency by a refrigerant inside the hollow shaft can be improved, and favorable sensing can be achieved.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A magnetic sensor device comprising:
a hollow shaft that is formed of a ferromagnetic body and holds a refrigerant at an inner circumferential side;
a magnet that is positioned at an outer circumferential side of the hollow shaft and includes N pole and S pole adjacent in a circumferential direction of the hollow shaft; and
a magnetic sensor that detects a magnetic field of the magnet, wherein
the hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.

2. The magnetic sensor device according to claim 1, wherein
as the first function, a product Bs×Ts of a saturation magnetic flux density Bs of the hollow shaft and a thickness Ts of the hollow shaft is defined, and
as the second function, a product Bm×Wm of a magnetic flux density Bm on a surface of the magnet at the inner circumferential side and a circumferential length Wm based on the adjacent N and S poles of the magnet is defined.

3. The magnetic sensor device according to claim 2, wherein
the circumferential length Wm based on the adjacent N and S poles of the magnet includes at least one of a circumferential width of the N pole, a circumferential width of the S pole, and a circumferential pitch between the N pole and the S pole.

4. The magnetic sensor device according to claim 2, wherein
Bs×Ts>Bm×Wm is satisfied.

5. The magnetic sensor device according to claim 1, wherein
the refrigerant has a density higher than a density of air.

6. The magnetic sensor device according to claim 1, wherein
the hollow shaft is formed of a ferromagnetic material whose thermal conductivity is equal to or higher than thermal conductivity of silicon steel.

7. The magnetic sensor device according to claim 1, wherein
the magnet is arranged between one end and the other end of the hollow shaft in an axial direction.

8. The magnetic sensor device according to claim 7, wherein
the magnetic sensor is arranged away from the hollow shaft in a radial direction of the hollow shaft between the one end and the other end of the hollow shaft in the axial direction.

9. A rotation detection system comprising:
the magnetic sensor device according to claim 1; and
a driving device that rotates the hollow shaft.

10. The rotation detection system according to claim 9 further comprising:
a supply device that supplies the refrigerant to the inner circumferential side of the hollow shaft.

11. A magnetic field generation device comprising:
a hollow shaft that is formed of a ferromagnetic body and holds a refrigerant at an inner circumferential side; and
a magnet that is positioned at an outer circumferential side of the hollow shaft and includes N pole and S pole adjacent in a circumferential direction of the hollow shaft, wherein
the hollow shaft and the magnet are configured so that a first function relating to a shape and characteristics of the hollow shaft and a second function relating to a shape and characteristics of the magnet satisfy a condition for reducing a leakage magnetic field from the magnet from the outer circumferential side to the inner circumferential side of the hollow shaft.
